(19) United States
(12) Patent Application Publication
(10) Pub. No.: US 2024/0297278 A1
(43) Pub. Date: Sep. 5, 2024

(54) MICRO LIGHT-EMITTING DIODE (LED) STRUCTURE

(71) Applicant: JADE BIRD DISPLAY (SHANGHAI) LIMITED, SHANGHAI (CN)

(72) Inventors: Yuankun ZHU, Shanghai (CN); Shuang ZHAO, Shanghai (CN); Deshuai LIU, Shanghai (CN)

(21) Appl. No.: 18/594,025

(22) Filed: Mar. 4, 2024

(30) Foreign Application Priority Data
Mar. 2, 2023 (WO) PCT/CN2023/079322

(51) Int. Cl. H01L 33/58; H01L 25/075; H01L 33/10; H01L 33/62

(52) U.S. Cl. CPC H01L 33/58; H01L 25/0753; H01L 33/10; H01L 33/62

(57) ABSTRACT

The present disclosure provides structures for a micro light-emitting diode (LED) array, to improve light extraction efficiency. An exemplary structure includes: a bottom epitaxial layer of a first conductive type, continuously formed across the micro LED array; a light-emitting layer, formed on the bottom epitaxial layer and continuously formed across the micro LED array; a top epitaxial layer of a second conductive type, wherein the top epitaxial layer is formed on the light-emitting layer and continuously formed across the micro LED array; and a first trench, formed in the top epitaxial layer and between adjacent micro LED.

### CROSS-REFERENCE TO RELATED APPLICATIONS

The present disclosure claims priority to and the benefits of PCT Application No. PCT/CN2023/079322, filed on Mar. 2, 2023, which is incorporated herein by reference in its entirety.

### TECHNICAL FIELD

The present disclosure generally relates to the technical field of micro light-emitting diodes (micro LEDs), and more particularly, to a micro LED structure that improves light-extraction efficiency.

### BACKGROUND

The micro LED showed higher output performance than conventional LEDs due to better strain relaxation, improved light extraction efficiency, and uniform current spreading. The micro LED also exhibited improved thermal effects, higher current density, faster response rate, larger working temperature range, higher resolution, wider color gamut, higher contrast, and lower power consumption, as compared with conventional LEDs.

To achieve higher pixel density, the size of the micro LED is reduced to less than several micrometers. However, the efficiency and the carrier lifetime of the micro LED array-based device degrades drastically with reducing the micro LED size to a large extent, by surface recombination and poor p-type conduction induced by top-down etching. The performance of micro LED also suffers severely from quantum-confined stark effect, particularly due to the strain-induced polarization field, which leads to unstable operation and significant variations in emission wavelengths with increasing current. Additionally, with the decrease of the micro LED diameter, a large number of surface states and defects are formed at the surface of the micro LED structure by inductively coupled plasma (ICP) etching, which increases the non-radiation recombination at the surface of the micro LED structure.

Additionally, the emission of the conventional micro LED structure is mainly distributed at any direction which exhibits poor directional emission and reduces the light intensity along the vertical direction. To realize the directional emission of the micro LED structure, extra reflective structures are configured around the mesa of the micro LED structure and at the bottom of the mesa, so as to reflect the emission light to a same direction, which causes a complex manufacturing process and increases the cost of the micro LED.

To avoid the crosstalk between the adjacent micro LEDs, an isolation structure is conventionally formed outside and around a single micro LED, thereby increasing the volume of the micro LED and decreasing the integration of the micro-display panel, and further reducing the resolution of the micro LED panel. Furthermore, the isolation structure is formed high enough to isolate the light crosstalk between the adjacent micro LEDs, thereby further increasing the volume of the micro LED. If the isolation structure is not formed at sufficient height, the crosstalk between the adjacent micro LED will not be efficiently inhibited.

Furthermore, in micro LED array-based devices, one micro LED is conventionally used as one pixel, such as in monolithic micro LED array panel. However, the micro LED structure with smaller diameter shows lower external quantum efficiency (EQE), which reduces the light efficiency of each pixel. Thus, despite the above technical benefits associated with the micro LEDs, the existing pixel structure's light extraction efficiency is low. Here, “light extraction efficiency” is a ratio of the light energy actually emitted by the micro LED unit over the light energy generated by the micro LED unit. It is used to describe the phenomena that the electrically excited photons generated inside a micro LED unit are not all emitted, but rather only a portion of the photons can leave the micro LED unit via refraction. The remaining photons are repeatedly reflected inside the micro LED unit until they are eventually absorbed.

### SUMMARY

In view of the technical problems associated with the low light extraction efficiency in existing micro LED structures, the present disclosure proposes to form photonic crystals on a semiconductor surface of an epitaxial layer, to improve the light extraction efficiency of the micro LED structure.

According to some disclosed embodiments, an exemplary structure for a micro LED array is provided. The structure comprises: a bottom epitaxial layer of a first conductive type, continuously formed across the micro LED array; a light-emitting layer, formed on the bottom epitaxial layer and continuously formed across the micro LED array; a top epitaxial layer of a second conductive type, wherein the top epitaxial layer is formed on the light-emitting layer and continuously formed across the micro LED array; and a first trench, formed in the top epitaxial layer and between adjacent micro LEDs.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

FIG. 1 is a cross-sectional view schematically showing an exemplary micro LED structure, according to some embodiments of the present disclosure.

FIG. 2 is a schematic plan view of a top epitaxial layer in the micro LED structure of FIG. 1, according to some embodiments of the present disclosure.

FIG. 3 is a schematic plan view of a top-connected structure in the micro LED structure of FIG. 1, according to some embodiments of the present disclosure.

FIG. 4 is a schematic bottom view of a bottom epitaxial layer in the micro LED structure of FIG. 1, according to some embodiments of the present disclosure.

FIG. 5 is a cross-sectional view schematically showing another exemplary micro LED structure, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

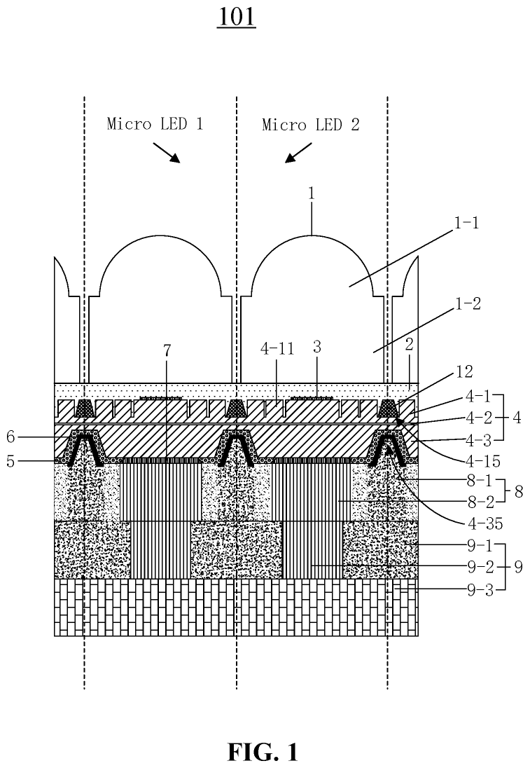

FIG. 1 a cross-sectional view schematically showing an exemplary micro LED structure 101 that has improved light extraction efficiency, according to some embodiments of the present disclosure. More particularly, the micro LED structure 101 is used for an LED display device that comprises an array of micro LEDs, which is formed in a micro LED display panel. Thus, the micro LED structure 101 comprises a plurality of micro LEDs. FIG. 1 shows a portion of the array of micro LEDs. One or more micro LEDs in the micro LED structure 101 can form a pixel of the micro LED display panel. For example, in some embodiments, each micro LED in the micro LED structure 101 forms a different pixel; whereas in some other embodiments, two or more micro LEDs form one pixel, in which each of the two or more micro LEDs form a different color component of the pixel.

As shown in FIG. 1, each micro LED in the micro LED structure 101 may have an identical structure. The micro LED structure 101 includes an epitaxial layer 4, which further includes a bottom epitaxial layer 4-3, a light-emitting layer 4-2 formed on the bottom epitaxial layer 4-3, and a top epitaxial layer 4-1 formed on the light-emitting layer 4-2. The bottom epitaxial layer 4-3 has a first conductive type, and the top epitaxial layer 4-1 has a second conductive type. For example, the first conductive type may be N-type, and the second conductive type may be P-type. As another example, the first conductive type may be P-type, and the second conductive type may be N-type. It is noted that the epitaxial layer 4 at least comprises one of inorganic materials in some embodiments or one of organic materials in another some embodiments.

Next, details of the top epitaxial layer 4-1, light-emitting layer 4-2, and bottom epitaxial layer 4-3 are described.

As shown in FIG. 1, several structures are formed in the top epitaxial layer 4-1. Specifically, a first trench 4-15 is formed in the top epitaxial layer 4-1 between the adjacent micro LEDs. In some embodiments, the first trench 4-15 does not extend through the bottom of the top epitaxial layer 4-1, i.e., the bottom of the first trench (4-15) is not lower than the bottom of the top epitaxial layer 4-1; whereas in some other embodiments, the first trench 4-15 can extend through the bottom of the top epitaxial layer 4-1 to the light-emitting layer 4-2. Moreover, a top-connected structure 12 is formed on top epitaxial layer 4-1 and between adjacent micro pixel structures. The top of top-connected structure 12 is not lower than the top of top epitaxial layer 4-1.

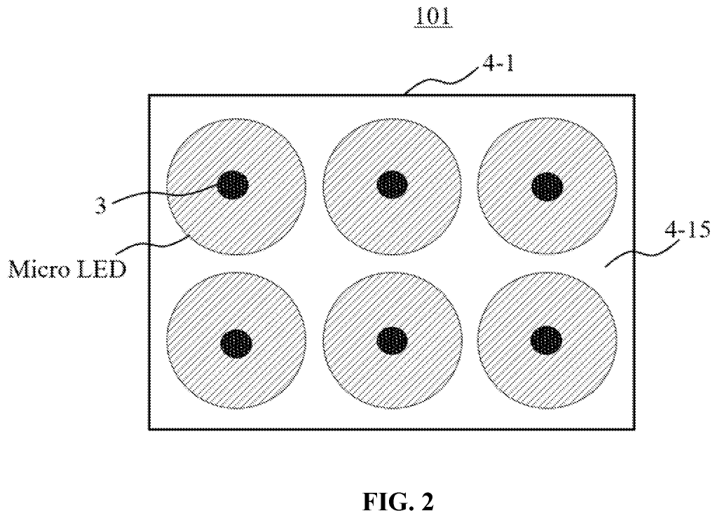

The first trench 4-15 partitions the top epitaxial layer 4-1 into an array of micro LEDs. FIG. 2 is a schematic plan view of the top epitaxial layer 4-1 with the first trench 4-15, according to some embodiments of the present disclosure. For simplicity, only six micro LEDs are shown in FIG. 2, but it is contemplated that any number of micro LEDs may be present in the micro LED structure 101. Moreover, only structures relevant to the present description are shown in FIG. 2, while other structures are skipped from showing. As shown in FIG. 2, the first trench 4-15 is continuously formed in the top epitaxial layer 4-1 and across the micro LED array. The first trench 4-15 divides the top epitaxial layer 4-1 into six micro LEDs.

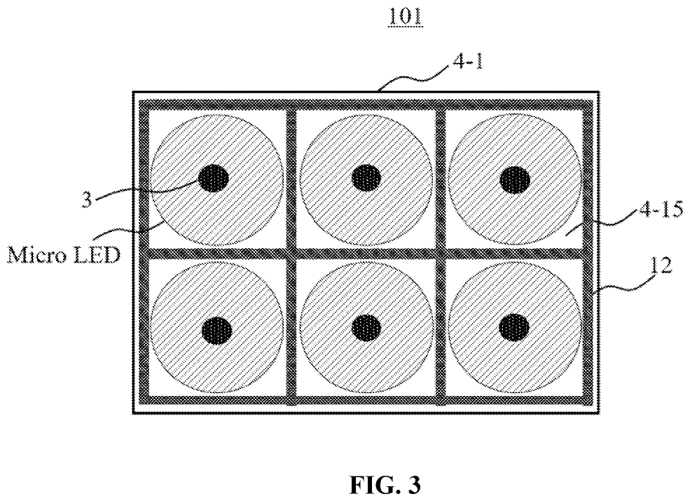

Referring back to FIG. 1, a top-connected structure 12 is formed in the first trench 4-15 and between adjacent micro LEDs. FIG. 3 is a schematic plan view of the top epitaxial layer 4-1 with the top-connected structure 12, according to some embodiments of the present disclosure. Except for the top-connected structure 12, FIG. 3 is otherwise identical to FIG. 2. As shown in FIG. 3, the top-connected structure 12 is continuously formed in the first trench 4-15 and across the micro LED array.

Referring back to FIG. 1, an array of top contacts 3 is formed on the top surface of the top epitaxial layer 4-1 and respectively formed in the array of micro LEDs. As shown in the plan views of FIGS. 2 and 3, in some embodiments, the top contacts 3 may be formed at or near to the centers of the respective micro LEDs. It is noted that, when the top contacts 3 are formed at or near the centers of the respective micro LEDs, each top contact 3 can be made as small as possible, such as a dot, such that it does not significantly shield the emitting light of the respective micro LED. The top-connected structure 12 may form a closed shape around the micro LED array. The closed shape completely surrounds the entire array of micro LEDs, and/or completely surrounds each of the micro LEDs. For example, as shown in FIGS. 2 and 3, the top-connected structure 12 forms a grid. The grid has a closed outer boundary that completely surrounds the entire array of micro LEDs. Each cell of the grid also completely surrounds the respective top contact 3.

Referring back to FIG. 1, in some embodiments, a top conductive layer 2 is continuously formed on the top epitaxial layer 4-1 and across the array of micro LEDs. The top conductive layer 2 may be transparent and may be made of oxide semiconductor-indium tin oxide (ITO). The array of top contacts 3 is located between the top epitaxial layer 4-1 and the top conductive layer 2. The array of the top contacts and the top-connected structure 12 are electrically connected by the top conductive layer 2. The array of the top contacts comprises a conductive material, e.g., metal, and can form an ohmic contact with the top conductive layer 2. Moreover, the top-connected structure 12 comprises a conductive material, e.g., metal, and can form an ohmic contact with the top conductive layer 2. In some embodiments, the array of the top contacts and the top-connected structure 12 may comprise the same type of conductive material, e.g., the same metal. In some embodiments, the top-connected structure 12 is not necessary when the top conductive layer 2 is used to electrically connect the array of contact pads 3; therefore, the top-connected structure 12 is optional and can be omitted from the micro LED structure 101.

Still referring to FIG. 1, in some embodiments, to improve the light extraction efficiency within the micro LED structure 101, the top epitaxial layer 4-1 is configured to form a plurality of photonic crystals 4-11 at an interface between the top epitaxial layer 4-1 and the top conductive layer 2. Consistent with the disclosed embodiments, the plurality of photonic crystals 4-11 may be configured to have shapes and sizes that are suitable for improving the light extraction efficiency. For example, as shown in FIG. 1, each of the plurality of photonic crystals 4-11 may have a cylindrical shape. As another example, each of the plurality of photonic crystals 4-11 has a height of approximately 300 nm and a diameter of approximately 266 nm, and adjacent photonic crystals 4-11 may be spaced by a distance of approximately 50 nm. Nonetheless, the disclosed embodiments are not limited to any particular shape or dimensions of the photonic crystals.

Still referring to FIG. 1, an array of micro lenses 1 is formed on the top conductive layer 2. The array of micro lenses 1 is respectively located in the array of micro LEDs. Micro lenses 1 in adjacent micro LEDs are separated by a gap that exposes the top-connected structure 12 to the air. Each micro lens 1 includes a top hemisphere lens 1-1 and a bottom spacer 1-2 below top hemisphere lens 1-1. A width of the bottom spacer 1-2 is greater than a width (i.e., diameter) of top hemisphere lens 1-1. A height of bottom spacer 1-2 is determined based on the width (i.e., diameter) of top hemisphere lens 1-1.

In some alternative embodiments not shown in FIGS. 1-3, rather than being formed at or near the centers of the respective micro LEDs, the array of top contacts top 3 is formed between adjacent micro LEDs (i.e., at the edge of each micro LED) and on the top surface of the top epitaxial layer 4-1. For example, in this alternative configuration, the array of top contacts 3 can be formed on the top surface of the top epitaxial layer 4-1 and at the bottom of the top-connected structure 12. For example, the array of top contacts 3 and the top-connected structure 12 are continuously formed in the first trench 4-15. In this configuration, because the first trench 4-15 is continuously formed across the micro LED array, the array of top contacts 3 and the top-connected structure 12 each form a continuous structure across the micro LED array. Moreover, in some embodiments, the top conductive layer 2 is not needed when the array of top contacts 3 is formed at the bottom of the top-connected structure 12.

Although FIG. 1 shows that the bottom of the first trench 4-15 is flat, the present disclosure does not limit the shape of the first trench 4-15. In some alternative embodiments, the bottom of the first trench 4-15 is not flat. For example, in some embodiments, the bottom of the first trench 4-15 comprises one or more sub-trenches. For example, in some embodiments, the bottom of the first trench 4-15 comprises one or more first sharp tips. In some embodiments, one first sharp tip is formed at the bottom of the first trench 4-15. In some embodiments, one first sharp tip is formed at the center of the bottom of the first trench 4-15. In some embodiments, the first sharp tip is used as the first trench 4-15; that is, the first trench 4-15 is replaced by the first sharp tip. In some embodiments, the first sharp tip is formed at the edge of the bottom of the first trench 4-15. Furthermore, the bottom of the first sharp tip is lower than the bottom of the first trench 4-15. The array of top contacts 3 is further formed in the first sharp tip and connected with the top conductive layer 2. In some embodiments, the top-connected structure 12 is further formed in the first sharp tip and connected with the top conductive layer 2. In some embodiments, the array of top contacts 3 is further formed in the first sharp tip, and the top-connected structure 12 is further formed in the first sharp tip, while the top conductive layer 2 is not necessary.

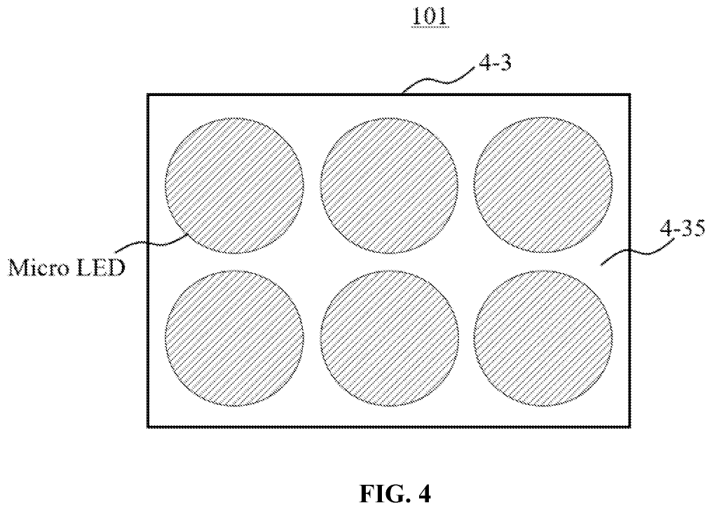

Referring to FIG. 1, a second trench 4-35 is formed in the bottom epitaxial layer 4-3 and between adjacent micro LEDs. The second trench 4-35 partitions the bottom epitaxial layer 4-3 into an array of areas corresponding to the array of micro LEDs. FIG. 4 is a schematic bottom view of the bottom epitaxial layer 4-3 with the second trench 4-35, according to some embodiments of the present disclosure. For simplicity, only six micro LEDs are shown in FIG. 4, but it is contemplated that any number of micro LEDs may be present in the micro LED structure 101. Moreover, only structures relevant to the present description are shown in FIG. 4, while other structures are skipped from showing. As shown in FIG. 4, the second trench 4-35 is continuously formed in the bottom epitaxial layer 4-3 and across the micro LED array. The second trench 4-35 divides the bottom epitaxial layer 4-3 into six micro LEDs.

Referring back to FIG. 1, in some embodiments, the second trench 4-35 does not extend through the top of the bottom epitaxial layer 4-3, i.e., the top of the second trench 4-35 is not higher than the top of the bottom epitaxial layer 4-3. But in some alternative embodiments, the second trench 4-35 can extend to the light-emitting layer 4-2. The inner surface of the second trench 4-35 is covered by an insulating layer 5. And furthermore, a reflective layer 6 is formed on the surface of the insulating layer 5. The inner surfaces of the second trenches 4-35 form an array of sidewalls at a bottom surface of the bottom epitaxial layer 4-3. The reflective layer 6 covers the array of sidewalls. The insulating layer 5 is formed between the array of sidewalls and the reflective layer 6. An array of bottom contacts 7 are formed at the bottom surface of bottom epitaxial layer 4-3 and respectively corresponds to the array of micro LEDs. Each bottom contact 7 is surrounded by the insulating layer 5 and insulated by the insulating layer 5 from the neighboring bottom contact 7. The array of bottom contacts 7 is electrically connected with a bottom conductive structure 8 formed below bottom epitaxial layer 4-3. Specifically, bottom conductive structure 8 includes a first dielectric layer 8-1 and a first array of contact holes 8-2 formed in first dielectric layer 8-1. The first array of contact holes 8-2 respectively corresponds to the array of micro LEDs. Each contact hole 8-2 in the first array may have a cylindrical shape. The first array of contact holes 8-2 is filled with conductive material, such as metal. The array of bottom contacts 7 is electrically connected to bottom conductive structure 8 by forming an ohmic contact with the metal filled in the first array of contact holes 8-2, respectively. It is noted that the reflective layer 6 is not connected with the array of bottom contacts 7 and the first array of contact holes 8-2.

An integrated circuit (IC) back plane 9 is formed below and electrically connected to the bottom conductive structure 8. The IC back plane 9 includes a second dielectric layer 9-1 and a second array of contact holes 9-2 formed in the second dielectric layer 9-1. Each contact hole 9-2 in the second array may have a cylindrical shape. The second array of contact holes 9-2 forms a one-to-one corresponding relationship with the first array of contact holes 8-2. A width of a contact hole 8-2 in the first array may be greater than, smaller than, or equal to a width of a corresponding contact hole 9-2 in the second array. The second array of contact holes 9-2 is filled with conductive material, such as metal, to form an ohmic contact with the conductive material filled in the first array of contact holes 8-2. The bottom conductive structure 8 is bonded with the IC back plane 9 by bonding the conductive material (e.g., metal) in the first array of contact holes 8-2 with the conductive material (e.g., metal) in the second array of contact holes 9-2. The IC back plane 9 further includes a chip circuit board 9-3 formed below the second dielectric layer 9-1 and the second array of contact holes 9-2.

Although FIG. 1 shows that the top of the second trench 4-35 is flat, the present disclosure does not limit the shape of the second trench 4-35. In some embodiments, the top of the second trench 4-35 is not flat. For example, the top of the second trench 4-35 comprises one or more second sharp tips. In some embodiments, one second sharp tip is formed at the top of the second trench 4-35, and the top of the second sharp tip is higher than the top of the second trench 4-35. In some embodiments, one second sharp tip is formed at the center of the top of the second trench 4-35. In some embodiments, the second sharp tip is used as the second trench 4-35; that is, the second trench 4-35 is replaced by the second sharp tip. In some embodiments, the second sharp tip is formed at the edge of the top of the second trench 4-35. Furthermore, the top of the second sharp tip is higher than the top of the second trench 4-35. The insulating layer 5 is further formed in the second sharp tip. Furthermore, the reflective layer 6 is further formed on the insulating layer 5 in the second sharp tip.

In some embodiments, the light-emitting layer 4-2 includes one or more layers of an InGaP/AlGaInP quantum well, each layer of the InGaP/AlGaInP quantum well including an InGaP sub-layer and an AlGaInP sub-layer. For example, the light-emitting layer 4-2 may include 1-20 layers of InGaP/AlGaInP quantum well. As another example, in each layer of InGaP/AlGaInP quantum well, the thickness of the InGaP sub-layer is approximately 3.5 nm, and the thickness of the AlGaInP sub-layer is approximately 6.5 nm. The above exemplary numerical values are for illustrative purposes only and are not intended to be used to limit the present disclosure.

Consistent with the disclosed embodiments, one or more of the top epitaxial layer 4-1, light-emitting layer 4-2, or bottom epitaxial layer 4-3 form a continuous structure across the array of micro LEDs. In some embodiments, the bottom epitaxial layer 4-3 is interconnected between adjacent micro LEDs. Specifically, the top surface of the bottom epitaxial layer 4-3 continuously extends across the array of micro LEDs. Moreover, the top epitaxial layer 4-1 is interconnected between adjacent micro LEDs. Specifically, the bottom surface of the top epitaxial layer 4-1 continuously extends across the array of micro LEDs. Moreover, the light-emitting layer 4-2 is interconnected between adjacent micro LEDs. In some embodiments, the light-emitting layer 4-2 is continuously formed in the whole micro LED array; the bottom epitaxial layer 4-3 is continuously formed at the bottom surface of the light-emitting layer 4-2, and the top epitaxial layer 4-1 is continuously formed on the top surface of the light-emitting layer 4-2.

In some embodiments, the top epitaxial layer 4-1 may further include: a GaAs layer having a thickness between 100 nm-200 nm, inclusive; an AlGaInP layer having a thickness between 100 nm-200 nm, inclusive; an n-GaAs (i.e., N-type GaAs) layer having a thickness between 10 nm-20 nm, inclusive; and/or a Si-doped n-AlInP (i.e., N-type AlInP) layer having a thickness between 50 nm-300 nm, inclusive. The above exemplary numerical values are for illustrative purposes only and are not intended to be used to limit the present disclosure.

In some embodiments, to enhance electric current expansion performance between adjacent micro LEDs, the top epitaxial layer 4-1 is configured to form an integrated connected structure over the array of micro LEDs, i.e., top epitaxial layer 4-1 is interconnected between adjacent micro LEDs. Additionally or alternatively, the top-connected structure 12 is disposed on top epitaxial layer 4-1, to further enhance the current expansion performance between adjacent micro LEDs.

In some embodiments, to improve the quantum wells' well plug effect (WPE) performance, the light-emitting layer 4-2 is configured to form an integrated connected structure over the array of micro LEDs, i.e., the light-emitting layer 4-2 is interconnected between adjacent micro LEDs. “WPE” is defined as the ratio of optical output power over consumed electrical input power as measured at a wall plug. By forming the light-emitting layer 4-2 as an integrated connected structure over the array of micro LEDs, high WPE can be achieved in the micro LED structure 101, thereby ensuring high performance of the LED display device.

In some embodiments, the bottom epitaxial layer 4-3 includes a Mg-doped p-AlInP layer having a thickness between 50 nm-300 nm, inclusive. These numerical values are for exemplary purposes only and are not intended to be used to limit the present disclosure.

As shown in FIG. 1, in some embodiments, the bottom epitaxial layer 4-3 forms an array of inverted trapezoidal shapes or an array of bowl shapes at an interface between the bottom epitaxial layer 4-3 and the bottom conductive structure 8.

FIG. 1 also shows an exemplary structure to achieve bonding between the bottom conductive structure 8 and the IC back plane 9. Specifically, the bottom conductive structure 8 includes a first dielectric layer 8-1 and a first array of cylindrical contact holes 8-2. The first array of cylindrical contact holes 8-2 is formed in the first dielectric layer 8-1. A first metal is filled in the first array of cylindrical contact holes 8-2. The IC back plane 9 includes a second dielectric layer 9-1, a second array of cylindrical contact holes 9-2, and a chip circuit board 9-3. The second array of cylindrical contact holes 9-2 is formed in the second dielectric layer 9-1. A second metal is filled in the second array of cylindrical contact holes 9-2. The first metal in the first array of cylindrical contact holes 8-2 is respectively bonded to the second metal in the second array of cylindrical contact holes 9-2.

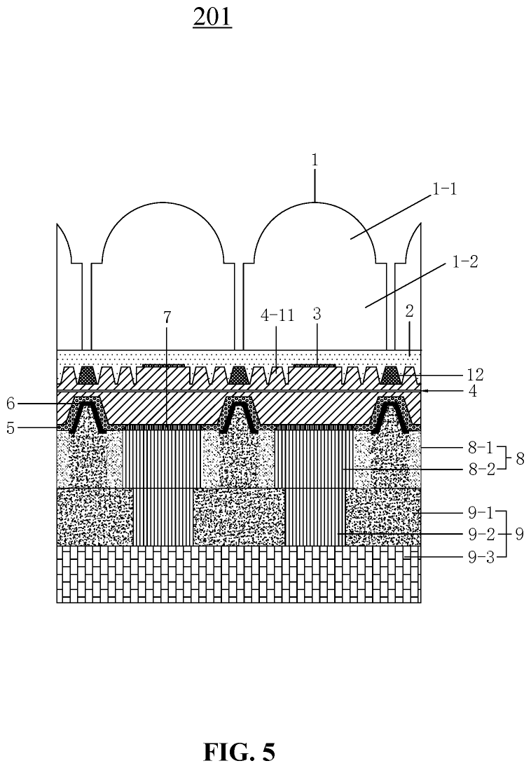

As described above, the photonic crystals 4-11 can have any suitable shape and are not limited to the cylindrical shape shown in FIG. 1. FIG. 5 is a cross-sectional view schematically showing an exemplary micro LED structure 201 with improved light-extraction efficiency, according to some embodiments of the present disclosure. As shown in FIG. 5, micro LED structure 201 is generally similar to the micro LED structure 101 (FIG. 1), with the difference lying in the shape and/or size of the photonic crystals. Specifically, each photonic crystal 4-11 in the micro LED structure 201 is etched to form a conical shape.

In sum, as described above, the disclosed micro LED structures (e.g., the micro LED structure 101 in FIG. 1 and the micro LED structure 201 in FIG. 5) have multiple photonic crystals and a continuous light-emitting layer, which results in improved light extraction efficiency. The disclosed micro pixel structures can be fabricated using any methods known in the art, including but not limited to, e.g., etching, deposition, etc.

According to some disclosed embodiments, an exemplary pixel structure includes: an integrated circuit (IC) chip layer; a first dielectric layer disposed on the IC chip layer; an array of P-electrode contact pads disposed on the first dielectric layer, the array of P-electrode contact pads respectively corresponding to an array of pixels; an insulating layer disposed on the first dielectric layer to surround and insulate each of the P-electrode contact pads; a reflecting layer disposed between the first dielectric layer and the insulating layer; an epitaxial wafer disposed on the array of P-electrode contact pads and the insulating layer; a transparent conductive layer disposed on the epitaxial wafer; an array of N-electrode contact pads disposed between the epitaxial wafer and the transparent conductive layer, the array of N-electrode contact pads respectively corresponding to the array of pixels; and an array of pixel lenses disposed on the transparent conductive layer, the array of pixel lenses respectively corresponding to the array of pixels; wherein the epitaxial wafer comprises an N-type semiconductor epitaxial layer, a light-emitting layer, and a P-type semiconductor epitaxial layer, the light-emitting layer being interconnected between adjacent pixels, the N-type semiconductor epitaxial layer forming a plurality of photonic crystals at an interface between the N-type semiconductor epitaxial layer and the transparent conductive layer.

The disclosed pixel structure improves the light extraction efficiency of pixels by etching a structure of photonic crystals on the epitaxial wafer. Specifically, various shapes of photonic crystals can be used. And the photonic crystals in a pixel structure can be arranged according to various pitches. For example, the shape of the photonic crystals can be cylindrical or conical. For another example, the pitch of the photonic crystals is determined by the etching depth and spacing distance between adjacent photonic crystals.

Moreover, in the disclosed pixel structure, the light-emitting layer is interconnected between adjacent pixels. Such interconnected quantum well structure enhances the performance of micro LED chips.

According to some disclosed embodiments, the shape of the photonic crystals can be designed according to experimental data regarding the light extraction efficiency. For example, the photonic crystals may be designed to be cylindrical or conical. Such shapes generally can achieve satisfactory light extraction efficiency.

Consistent with the disclosed embodiments, the photonic crystals can have any suitable height, diameter, and/or spacing distance. For example, the photonic crystals may have a height of 300 nm, and/or a diameter of 266 nm. And adjacent photonic crystals may be separated by a spacing distance of 50 nm.

The present invention is further set up as follows: The N-type semiconductor epitaxial layer between adjacent pixels is set as an integrated connected structure.

According to some disclosed embodiments, the N-type semiconductor epitaxial layer is interconnected between adjacent pixels, so as to form an interconnected structure across the array of pixels. Such interconnected N-type semiconductor epitaxial layer facilitates electric current expansion.

According to some disclosed embodiments, the P-type semiconductor epitaxial layer forms an array of inverted trapezoidal shapes or an array of bowl shapes at an interface between the P-type semiconductor epitaxial layer and the first dielectric layer. This way, the bottom of the inverted trapezoidal structure or bowl structures can reflect the light emitted from the quantum well to its periphery, so as to further gather the light and improve light utilization.

According to some disclosed embodiments, the transparent conductive layer is N-type oxide semiconductor-indium tin oxide (ITO). The ITO improves electric current expansion between adjacent pixels.

According to some disclosed embodiments, the first dielectric layer includes a first dielectric material and a first metal. A first array of cylindrical contact holes is formed in the first dielectric material and the first metal is filled in the first array of cylindrical contact holes. Moreover, the IC chip layer includes a second dielectric layer, second metal, and a chip circuit board. The second dielectric layer includes a second array of cylindrical contact holes and the second metal is filled in the second array of cylindrical contact holes. The first metal in the first array of cylindrical contact holes is respectively bonded to the second metal in the second array of cylindrical contact holes. This way, the first dielectric layer is bonded to the IC chip layer.

In sum, the disclosed pixel structures improve the light extraction efficiency of pixels by etching a structure of photonic crystals on the epitaxial wafer. Specifically, the shape and pitch of the photonic crystals can be designed in different ways. For example, the shape of photonic crystals can be cylindrical or conical, and the pitch of the photonic crystals is determined by the etching depth and spacing distance of adjacent photonic crystals. Moreover, the quantum well between adjacent pixels is formed as an integrated connected structure across the array of pixels. Such integrated connected quantum well enhances the performance of micro LED chips.

As used herein, unless specifically stated otherwise, the term “or” encompasses all possible combinations, except where infeasible. For example, if it is stated that a database may include A or B, then, unless specifically stated otherwise or infeasible, the database may include A or B, or A and B. As a second example, if it is stated that a database may include A, B, or C, then, unless specifically stated otherwise or infeasible, the database may include A or B, or C, or A and B, or A and C, or B and C, or A and B and C.

It will be appreciated that the embodiments of the present disclosure are not limited to the exact construction that has been described above and illustrated in the accompanying drawings, and that various modifications and changes may be made without departing from the scope thereof. While the present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

What is claimed is:

1. A micro light-emitting diode (LED) structure for an array of micro LEDs, wherein the micro LED structure comprises:
a bottom epitaxial layer of a first conductive type, continuously formed across the micro LED array;
a light-emitting layer, formed on the bottom epitaxial layer and continuously formed across the micro LED array;
a top epitaxial layer of a second conductive type, wherein the top epitaxial layer is formed on the light-emitting layer and continuously formed across the micro LED array; and
a first trench, formed in the top epitaxial layer and between adjacent micro LEDs.

2. The micro LED structure according to claim 1, further comprising a second trench, formed in the bottom epitaxial layer and between adjacent micro LEDs, wherein the second trench is continuously formed across the micro LED array.

3. The micro LED structure according to claim 2, wherein a top of the second trench is not higher than a top of the bottom epitaxial layer.

4. The micro LED structure according to claim 1, wherein a bottom of the first trench is not lower than a bottom of the top epitaxial layer.

5. The micro LED structure according to claim 1, further comprising:
a top conductive layer, formed on the top epitaxial layer;
a bottom conductive structure, formed below the bottom epitaxial layer; and
a top-connected structure, formed in the first trench and between adjacent micro LEDs.

6. The micro LED structure according to claim 5, wherein the first trench is continuously formed across the micro LED array, and the top-connected structure is continuously formed in the first trench and across the micro LED array.

7. The micro LED structure according to claim 6, wherein the top-connected structure forms a closed shape around the micro LED array.

8. The micro LED structure according to claim 5, wherein a top of the top-connected structure is not lower than atop of the top epitaxial layer.

9. The micro LED structure according to claim 5, wherein the top-connected structure comprises a conductive material and forms an ohmic contact with the top conductive layer.

10. The micro LED structure according to claim 9, wherein the conductive material of the top-connected structure is metal.

11. The micro LED structure according to claim 5, further comprising an array of top contacts, formed between the top epitaxial layer and the top conductive layer.

12. The micro LED structure according to claim 11, wherein:
the array of top contacts comprises a conductive material and forms an ohmic contact with the top conductive layer; and
the array of top contacts is respectively located at centers of the array of micro LEDs.

13. The micro LED structure according to claim 11, wherein the top-connected structure and the array of top contacts comprise a same conductive material.

14. The micro LED structure according to claim 1, further comprising an array of micro lenses formed above the top epitaxial layer.

15. The micro LED structure according to claim 5, further comprising an array of micro lenses formed on the top conductive layer, wherein gaps are formed between adjacent micro lenses to expose the top-connected structure to air.

16. The micro LED structure according to claim 14, wherein each of the micro lenses comprises a top hemisphere lens and a bottom spacer below the top hemisphere lens.

17. The micro LED structure according to claim 16, wherein a width of the bottom spacer is greater than a diameter of the top hemisphere lens.

18. The micro LED structure according to claim 16, wherein a height of the bottom spacer is determined based on a diameter of the top hemisphere lens.

19. The micro LED structure according to claim 5, wherein the array of micro LEDs respectively forms an array of sidewalls at a bottom surface of the bottom epitaxial layer, and wherein the micro LED structure further comprises a reflective layer covering the array of sidewalls.

20. The micro LED structure according to claim 19, further comprising an insulating layer formed between the array of sidewalls and the reflective layer.

21. The micro LED structure according to claim 20, further comprising an array of bottom contacts formed at a bottom surface of the bottom epitaxial layer, wherein each of the bottom contacts is surrounded by the insulating layer and electrically connected with the bottom conductive structure.

22. The micro LED structure according to claim 21, wherein the array of bottom contacts forms an ohmic contact with the bottom conductive structure.

23. The micro LED structure according to claim 1, further comprising an array of bottom contacts formed at a bottom surface of the bottom epitaxial layer and electrically connected with a bottom conductive structure.

24. The micro LED structure according to claim 5, further comprising an integrated circuit (IC) back plane formed below and electrically connected to the bottom conductive structure.

25. The micro LED structure according to claim 24, wherein:
the bottom conductive structure comprises a first dielectric layer and a first array of contact holes formed in the first dielectric layer; and
the IC back plane comprises a second dielectric layer and a second array of contact holes formed in the second dielectric layer, the second array of contact holes respectively corresponding to the first array of contact holes.

26. The micro LED structure according to claim 25, wherein each contact hole in the first array has a width greater than a width of the corresponding contact hole in the second array.

27. The micro LED structure according to claim 25, wherein the first array of contact holes and the second array of contact holes are filled with metal.

28. The micro LED structure according to claim 25, wherein the IC back plane further comprises:
a chip circuit board formed below the second dielectric layer and the second array of contact holes.

29. The micro LED structure according to claim 24, wherein the bottom conductive structure is bonded with the IC back plane.

30. The micro LED structure according to claim 1, wherein the top epitaxial layer comprises a plurality of photonic crystals, each of the plurality of photonic crystals having a cylindrical shape or a conical shape.

31. The micro LED structure according to claim 30, wherein each of the plurality of photonic crystals has a height of 300 nm and a diameter of 266 nm, and adjacent photonic crystals are spaced by a distance of 50 nm.

32. The micro LED structure according to claim 1, wherein the top epitaxial layer is interconnected between adjacent micro LEDs.

33. The micro LED structure according to claim 32, wherein the top epitaxial layer forms a continuous bottom surface across the micro LED array.

34. The micro LED structure according to claim 1, wherein the light-emitting layer is interconnected between adjacent micro pixel structures.

35. The micro LED structure according to claim 1, wherein the bottom epitaxial layer is interconnected between adjacent micro pixel structures.

36. The micro LED structure according to claim 35, wherein the bottom epitaxial layer forms a continuous top surface across the micro LED array.

37. The micro LED structure of a micro LED panel according to claim 1, wherein the bottom epitaxial layer forms an array of inverted trapezoidal shapes or an array of bowl shapes.

38. The micro LED structure according to claim 1, wherein:
the first conductive type is N-type and the second conductive type is P-type; or
the first conductive type is P-type and the second conductive type is N-type.

39. The micro LED structure according to claim 5, wherein the top conductive layer is transparent and comprises oxide semiconductor-indium tin oxide (ITO).

40. The micro LED structure according to claim 5, wherein the bottom conductive structure comprises an array of cylindrical contact holes filled with metal.
